(19) United States
(12) Patent Application Publication
(10) Pub. No.: US 2025/0043178 A1
(43) Pub. Date: Feb. 6, 2025

(54) Quantum Dot and Preparation Method Therefor, Composition, and Optoelectronic Device

(71) Applicants: ZHEJIANG UNIVERSITY, Hangzhou, Zhejiang (CN); Najing Technology Corporation Limited, Hangzhou, Zhejiang (CN)

(72) Inventors: Xiaogang PENG, Hangzhou, Zhejiang (CN); Jiongzhao LI, Hangzhou, Zhejiang (CN); Jiakuan ZHANG, Hangzhou, Zhejiang (CN)

(21) Appl. No.: 18/778,743

(22) Filed: Jul. 19, 2024

(30) Foreign Application Priority Data
Jul. 28, 2023 (CN) 202310941065.5

(51) Int. Cl. C09K 11/56

(52) U.S. Cl. CPC C09K 11/565

(57) ABSTRACT

The present disclosure provides a quantum dot and its preparation method, composition and optoelectronic device, the quantum dot includes an inner core and a ZnSe shell located on a surface of the inner core, wherein the ZnSe shell includes at least 4 ZnSe monolayers, surface ligands of the quantum dot include long chain linear zinc carboxylate ligands, branched-chain zinc carboxylate ligands, and short chain linear zinc carboxylate ligands, and the quantum dot is a spherical quantum dot. The quantum dot has a controllable shape and size and uniform morphology. The tensile strain generated inside the ZnSe shell due to lattice mismatch can be significantly alleviated, and the inner core experiences weaker compression strain. Under the synergistic effect of surface ligands of the quantum dot, the quantum dot has a PL quantum yield of close to 100%, and the photophysical stability and photochemical stability are improved.

### TECHNICAL FIELD

The present disclosure belongs to the technical field of photoelectric quantum dots, and relates to a quantum dot and a preparation method therefor, a composition, and an optoelectronic device.

### BACKGROUND

Colloidal quantum dots (QDs) are nanometer-sized fragments of the corresponding bulk single crystals, with sizes in the quantum-confined range. Their size- and composition-tunable optical/optoelectronic properties, coupled with excellent solution processability, have stimulated a great deal of interest in both fundamental research and technological applications. After more than 40 years of extensive research, scientists have realized that quantum dots with a narrow bandgap core and a wide bandgap epitaxial shell are essential for most purposes. However, controlled and reproducible synthesis of core/shell QDs with nearly ideal optical and optoelectronic properties largely remains challenging.

The most promising quantum dots as emissive materials are usually compound semiconductor nanocrystals, especially II-VI, II-V, and I-III-V nanocrystals. These semiconductors have the same crystal structures and similar lattice parameters, which means that some common semiconductors are wide bandgap epitaxial shells. In addition to a relatively wide bandgap, the shelling semiconductor should also have moderate lattice constants, be chemically durable, and have suitable precursors for epitaxial growth in hydrocarbon solvents at elevated temperatures. Despite the diverse composition of quantum dot cores, CdS and ZnSe are the two most studied shelling materials.

In addition, thin ZnS shell may grow as additional outer shells, with band gap that is too wide to ensure efficient charge injection and lattice constant that is too small to grow high-quality thick shell for most quantum dot cores. CdS shell is well known, mainly due to the successful synthesis of CdSe/CdS core/shell quantum dots of wurtzite and zinc blende and with near-ideal optical and optoelectronic properties. These quantum dots have been widely used in high-performance light-emitting diodes, biomedical labeling, lasers, and electrochemiluminescence. However, epitaxial CdS shell is inherently limited for two reasons. First, cadmium-free quantum dots are often the target due to environmental concerns. Second, while the bulk band gaps of both CdS (2.49 eV) and ZnSe (2.72 eV) are relatively wide and similar to each other, the bottom of the conduction band of CdS is about 0.7 to 0.9 eV lower than that of ZnSe, leading to type III (or quasi-III) band shifts in common narrow semiconductor core quantum dots, such as InP and CdSe. Thus, during epitaxial growth of the CdS shells, a substantial redshift of the QD band gap is unavoidable, and high-quality QD emitters in the blue to green emission window can hardly be synthesized with CdS shells. Overall, core/shell quantum dots with ZnSe shells (and possibly additional ZnS outer shells) are emerging as a major target in this field.

Therefore, how to obtain quantum dots with controllable size and shape and excellent optical properties is an urgent technical problem.

### SUMMARY

The present disclosure aims to provide a quantum dot and a preparation method therefor, a composition, and an optoelectronic device. The quantum dot structure provided by the present disclosure has a controllable shape and size and uniform morphology. The tensile strain generated inside the ZnSe shell due to lattice mismatch is significantly alleviated, and the inner core experiences weaker compression strain. Under the synergistic effect of surface ligands of the quantum dot, the quantum dot has a PL quantum yield of close to 100%, and the photophysical stability and photochemical stability are improved.

In order to achieve the above purpose, the present disclosure provides the following solutions:

According to one aspect of the present disclosure, a quantum dot is provided, including an inner core and a ZnSe shell located on a surface of the inner core, wherein the ZnSe shell includes at least 4 ZnSe monolayers, surface ligands of the quantum dot include long chain linear zinc carboxylate ligands, branched-chain zinc carboxylate ligands, and short chain linear zinc carboxylate ligands, and the quantum dot is a spherical quantum dot.

Preferably, the quantum dot exhibits a zinc-blende structure; a tensile strain borne by the ZnSe shell is 0-3%; a compression strain borne by the inner core is 1-3%.

Preferably, the quantum dot has a particle size of 4-12 nm.

Preferably, the ZnSe shell includes 4-16 ZnSe monolayers.

Preferably, the quantum dot has an average roundness greater than or equal to 0.8, more preferably greater than or equal to 0.9; the quantum dot has an average solidity greater than or equal to 0.8.

Preferably, the ZnSe shell has a bandgap greater than that of the inner core.

Preferably, a lattice constant of a material of the inner core differs from a lattice constant of the ZnSe shell by within +5%.

Preferably, a distribution density of the branched-chain zinc carboxylate ligand on the surface of the shell is less than that of the long chain linear zinc carboxylate ligand, and the distribution density of the branched-chain zinc carboxylate ligand on the surface of the shell is less than that of the short chain linear zinc carboxylate ligand.

Preferably, a ZnS shell is further provided on the surface of the ZnSe shell.

Preferably, the ZnS shell includes 1-3 ZnS monolayers, preferably 1.5-2.5 ZnS monolayers.

Preferably, the quantum dot includes the inner core and the ZnSe shell located on the surface of the inner core, the quantum dot has a full width at half maximum (FWHM) of 6-23 nm.

Preferably, the quantum dot further includes the ZnS shell, the quantum dot has an FWHM of 6-29 nm.

According second aspect of the present disclosure, a preparation method for a quantum dot is provided, including the following steps:
performing a first mixing of an inner core of a quantum dot, a first Se source, a long chain linear zinc carboxylate, a first short chain linear zinc carboxylate, and a first non-coordinating reaction medium to obtain a first reaction system, and carrying out a first heat treatment to obtain a core-shell quantum dot with a first shell thickness;
performing a second mixing of the core-shell quantum dot with the first shell thickness, a second Se source, a branched-chain zinc carboxylate, a second short chain linear zinc carboxylate, and a second non-coordinating reaction medium to obtain a second reaction system, and carrying out a second heat treatment to obtain the quantum dot;
wherein the quantum dot includes an inner core and a ZnSe shell located on a surface of the inner core; the ZnSe shell includes at least 4 ZnSe monolayers, and the quantum dot is a spherical quantum dot.

Preferably, a ratio of a molar amount of the first short chain linear zinc carboxylate to a molar amount of the long chain linear zinc carboxylate is 0-0.25 excluding 0.

Preferably, a ratio of a molar amount of Se in the first Se source to a sum of the molar amount of the long chain linear zinc carboxylate and the first short chain linear zinc carboxylate is 0-0.2 excluding 0.

Preferably, a linear, long chain of the long chain linear zinc carboxylate has 18-22 C atoms.

Preferably, a short chain of the first short chain linear zinc carboxylate has 6 C atoms or less, preferably 2-3.

Preferably, the first short chain linear zinc carboxylate includes zinc acetate and/or zinc propionate.

Preferably, the first non-coordinating reaction medium includes Vaseline and/or octadecene, preferably Vaseline and octadecene.

Preferably, the first mixing includes:
firstly, mixing the inner core of the quantum dot, the long chain linear zinc carboxylate, and the first non-coordinating reaction medium, and then adding the first Se source and the first short chain linear zinc carboxylate.

Preferably, the first heat treatment is performed at 280-300° C.

Preferably, the core-shell quantum dot with the first shell thickness has a shell thickness less than or equal to 2 nm.

Preferably, a ratio of a molar amount of the second short chain linear zinc carboxylate to a molar amount of the branched-chain zinc carboxylate is 0-0.5 excluding 0.

Preferably, a ratio of a molar amount of Se in the second Se source to a sum of the molar amount of the branched-chain zinc carboxylate and the second short chain linear zinc carboxylate is 0-0.33 excluding 0.

Preferably, the branched-chain zinc carboxylate has a structure represented by formula (I):

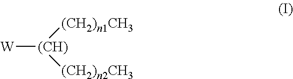

wherein in formula (I), n1 is 5-6, and n2 is 7-8; w is a carboxyl group.

Preferably, a short chain of the second short chain linear zinc carboxylate has 6 C atoms or less, preferably 2-3.

Preferably, the second short chain linear zinc carboxylate includes zinc acetate and/or zinc propionate.

Preferably, the second non-coordinating reaction medium includes Vaseline and/or octadecene, preferably Vaseline and octadecene.

Preferably, the second mixing includes:

mixing the core-shell quantum dot with the first shell thickness, the branched-chain zinc carboxylate, and the second non-coordinating reaction medium, and then adding the second Se source and the second short chain linear zinc carboxylate.

Preferably, the second heat treatment is performed at 280-300° C.

Preferably, a solution after the second heat treatment is subjected to a purification treatment, and a product after the purification treatment is subjected to a ZnS coating treatment.

Preferably, the ZnS coating treatment includes mixing a sulfur source, a third short chain linear zinc carboxylate, a medium chain linear carboxylic acid, a long straight-chain carboxylic acid, and a third non-coordinating reaction medium, and performing a third heat treatment to obtain a quantum dot coated with ZnS.

Preferably, a saturated short chain of the third short chain linear zinc carboxylate has 6 C atoms or less, preferably 2.

Preferably, the third short chain linear zinc carboxylate includes zinc acetate and/or zinc propionate.

Preferably, a linear, medium chain of the medium chain linear carboxylic acid has 8-14 C atoms, and the long straight-chain carboxylic acid includes oleic acid.

Preferably, the third non-coordinating reaction medium includes Vaseline and/or octadecene.

Preferably, the third heat treatment is performed at 300-310° C.;

Preferably, the third heat treatment is performed for 15-40 min.

According to third aspect of the present disclosure, a composition is provided, including the above quantum dot or the quantum dot prepared by the above preparation method.

According to fourth aspect of the present disclosure, an optoelectronic device, including the above quantum dot or the quantum dot prepared by the above preparation method.

Compared with the prior art, the present disclosure has the following beneficial effects:
(1) The quantum dot structure provided by the present disclosure has a controllable shape and size, uniform morphology, and a narrowed photoluminescent FWHM of a band edge emission. The tensile strain generated due to lattice mismatch in the ZnSe shell is significantly alleviated, and the inner core experiences weaker compression strain. Under the synergistic effect of the surface ligands of the quantum dot, the quantum dot has a PL quantum yield of close to 100%, and the photophysical stability and photochemical stability are improved.
(2) In the preparation process of the present disclosure, the preparation sequence and the selection of ligand types are indispensable. In the first step, the combination of the long chain linear zinc carboxylate and the first short chain linear zinc carboxylate is used for growing a thin ZnSe layer, allowing the crystal structure to maintain a virtually defect-free zinc-blende structure. Subsequently, the combination of the branched-chain zinc carboxylate and the second short chain linear zinc carboxylate is employed in the second step. The strong steric hindrance of the branched-chain zinc carboxylate results in only a small portion being coordinated to the surface (but it is sufficient to maintain the stability of the nanocrystalline colloid). Then, the remaining surface is adequately coordinated by the second short chain linear zinc carboxylate. Because the combination of the branched-chain zinc carboxylate and the second short chain linear zinc carboxylate causes higher activity of the whole surface (the binding effect is not as strong as that of the long chain linear zinc carboxylate), and anions and cations are introduced in a dropwise manner in the reaction, the growth process tends to be mainly driven by a thermodynamic force, and the surface atoms undergo reorganization towards a spherical shape. Ultimately, the obtained quantum dot is uniform in size, exhibits excellent dispersibility, has spherical morphology, and possesses an almost defect-free zinc-blende structure.

### BRIEF DESCRIPTION OF THE DRAWINGS

FIG. 1 shows TEM images of quantum dots according to Comparative Examples 1-4.

FIG. 2 is an XRD graph of the quantum dots according to Comparative Examples 1-4.

FIG. 3 is a graph of UV-Vis spectra and PL spectra of the quantum dots according to Comparative Examples 1-4.

FIG. 4 shows a comparison of PL peak positions of the quantum dots according to Comparative Examples 1-4.

FIG. 5 shows TEM images of quantum dots according to Examples 1-5 and a TEM image of the same CdSe inner core in Examples 1-6.

FIG. 6 is a graph of UV-Vis spectra and PL spectra of the quantum dots according to Examples 1-5.

FIG. 7 shows an XRD graph of quantum dots according to Examples 1 and 6 and a TEM image of the quantum dots according to Example 6.

FIG. 8 is a graph of UV-Vis spectra and PL spectra of the quantum dots according to Examples 6-10.

FIG. 9 is a PL decay dynamics curve graph of quantum dots according to Examples 6-10.

FIG. 10 shows the relationship between the ZnS shell thickness and PLQY of quantum dots according to Examples 6-12.

FIG. 11 is a graph of the PL spectrum of a single quantum dot in Examples 6-10.

FIG. 12 is an XRD graph of CdSe/ZnSe quantum dots (the preparation method of which is omitted with reference to Examples 1-5) with different shell thicknesses according to Examples 1-5 and other Examples of the present disclosure.

FIG. 13 shows the change rate of the relative lattice constants of the core and the shell of CdSe/ZnSe quantum dots (the preparation method of which is omitted with reference to Examples 1-5) with different shell thicknesses (the abscissa represents the number of ZnSe monolayers) according to Examples 1-5 and other Examples of the present disclosure.

FIG. 14 is a graph showing the PL spectra of single quantum dot in respective Examples 13-16 of the present disclosure.

### DETAILED DESCRIPTION

It is to be noted that the embodiments and the features in the embodiments in the present application may be combined with each other without conflict. The present disclosure will be described in detail below with reference to the accompanying drawings and in connection with the embodiments.

It should be noted that the terms “first”, “second”, “third” and the like in the specification and the claims of the present disclosure and the above-described drawings are used for distinguishing similar objects, and need not be used for describing a particular order or sequence. It should be understood that the data so used may be interchanged, where appropriate, for the embodiments of the present disclosure described herein.

For clarity, the terms “substantially” or “about” are used herein to imply the possibility of variations in values within acceptable ranges known to those skilled in the art. According to one example, the terms “substantially” or “about” as used herein should be interpreted to imply a possible variation of up to 10% above or below any specified value. According to another example, the terms “substantially” or “about” as used herein should be interpreted to imply a possible variation of up to 5% above or below any specified value. According to another example, the terms “substantially” or “about” as used herein should be interpreted to imply a possible variation of up to 2.5% above or below any specified value.

The technical solutions of the present disclosure are further described below by way of specific embodiments. It should be understood by those skilled in the art that the embodiments are only for facilitating the understanding of the present disclosure and should not be construed as the specific limitation of the present disclosure.

In one specific embodiment, the present disclosure provides a quantum dot including an inner core and a ZnSe shell located on the surface of the inner core. The ZnSe shell includes at least 4 ZnSe monolayers, surface ligands of the quantum dot include long chain linear zinc carboxylate ligands, branched-chain zinc carboxylate ligands, and short chain linear zinc carboxylate ligands, and the quantum dot is a spherical quantum dot.

The material of the inner core of the quantum dot provided by the present disclosure are not specifically limited, and inner core material that can be used for quantum dots as well as those known to the person skilled in the art are applicable to the present disclosure, including, but not limited to, CdSe, ZnSe, InP, ZnTe, CuInS₂, or AgInS₂, and the like.

The quantum dot structure provided by the present disclosure has a controllable shape and size, uniform morphology, and a narrowed FWHM. The tensile strain generated due to lattice mismatch in the ZnSe shell is significantly alleviated, and the inner core experiences weaker compression strain. Under the synergistic effect of the surface ligands of the quantum dot, the quantum dot has a PL quantum yield of close to 100%, and the photophysical stability and photochemical stability are improved.

According to the present disclosure, the surface of the quantum dot contains three kinds of ligand structures simultaneously. A small amount of the branched-chain zinc carboxylate ligands with stronger steric hindrance cover the crystal surface, thus increasing the coverage density of the short chain linear zinc carboxylate. Overall, the surface is fully coordinated. Additionally, the binding effect of the branched-chain zinc carboxylate ligand and the short chain linear zinc carboxylate on the surface is weaker than that of a conventional long chain linear zinc carboxylate, thus resulting in higher surface activity, and promoting the growth rates of the various facets to approximate each other, which is favorable for the formation of spherical morphology and achieving better size monodispersity. Additionally, the tensile strain of the inner core borne by different facets is evenly alleviated, ensuring that the tensile strain borne by the ZnSe shell is significantly released on the premise of maintaining high crystallinity, i.e., none of the three kinds of ligands is dispensable in the present disclosure.

As a preferred technical solution in one specific embodiment, the quantum dot exhibits a zinc-blende structure; the tensile strain borne by the ZnSe shell is 0-3%, e.g., 0.001%, 0.1%, 0.2%, 0.3%, 0.4%, 0.5%, 0.6%, 1%, 2%, or 3%; the compression strain borne by the inner core is 1-3%, e.g., 1%, 1.5%, 2%, 2.5%, or 3%.

The relative Raman shift (Δω/ω) of longitudinal phonons corresponding to the core and the shell is obtained by testing the Raman spectra of the quantum dots with different shell thicknesses, and the relative change rate of the lattice constant (Δα/α) can be obtained by using Grüneisen formula and correlating the Raman shift with the relative change of the corresponding lattice constant (Δα/α), that is, the tensile or compression strain is obtained through the testing.

In the present disclosure, the tensile strain borne by the ZnSe shell is 0%, which means that the tensile strain is about 0% through Raman spectrum testing, calculation, and characterization. The same crystal structure of the ZnSe shell and the inner core is achieved through the synergistic cooperation of the tensile strain of the ZnSe shell and the compression strain of the inner core. The limited change of the lattice constant in the growth process from the inner core to the ZnSe shell with different thicknesses ensures the relatively homogeneous growth of the ZnSe shell on the facets of the inner core. Ultimately, the quantum dot shows excellent size monodispersity and uniform morphology. If the tensile strain borne by the ZnSe shell is too large and exceeds 3%, strain energy caused by the lattice mismatch between two materials is accumulated continuously. When exceeding the critical thickness, certain facets will preferentially grow uncontrollably and present like islands, to alleviate the mismatching strain, which results in the deterioration of the crystallinity of the ZnSe shell and inconsistent morphology. If the compression strain of the inner core is too weak and less than 1%, it means that the ZnSe shell selectively grows at certain reaction sites with inconspicuous lattice mismatch at the initial growth stage, and ultimately fails to grow homogeneously. If the compression strain of the inner core is too large and exceeds 5%, the energy level structure of the quantum dot will be significantly changed with the presence of defective states affecting the photoluminescence efficiency.

As a preferred technical solution in one specific embodiment, the particle size of the quantum dot is 4-12 nm, e.g., 4 nm, 5 nm, 6 nm, 7 nm, 8 nm, 9 nm, 10 nm, 11 nm, or 12 nm.

The particle size of the quantum dot provided by the present disclosure is in a numerical range of the particle size of quantum dots only including the ZnSe shell.

As a preferred technical solution in one specific embodiment, the ZnSe shell includes 4-16 ZnSe monolayer (ML) structures, e.g., 4, 5, 6, 7, 8, 9, 10, 11, 12, 13, 14, 15, or 16.

The ZnSe shell provided by the present disclosure may use a greater number of ZnSe ML structures compared to conventional quantities. However, when the number of ZnSe ML structures exceeds 16, stacking faults occur, resulting in a reduction in photoluminescence efficiency.

Further, when the inner core is CdSe and the number of ZnSe ML structures exceeds 9, the photoluminescence efficiency of the quantum dot decreases. Therefore, 5-9 ZnSe ML structures are more preferred.

As a preferred technical solution in one specific embodiment, the quantum dot has an average roundness greater than or equal to 0.8, e.g., 0.8, 0.85, 0.9, 0.93, 0.95, 0.98, or 1, more preferably greater than or equal to 0.9; the quantum dot has an average solidity greater than or equal to 0.8, e.g., 0.8, 0.85, 0.9, 0.93, 0.95, 0.98, or 1.

The roundness and solidity in the present disclosure can be calculated by the same method with reference to the definition described in CN112442371A.

For the quantum dot provided by the present disclosure, if the roundness and the solidity fall within the ranges described above, the quantum dot exhibits good sphericity, and regular (irregular means that the quantum dot has sharp corners or concave surfaces) and uniform particle morphology, which is conducive to the photoluminescent property of the quantum dot.

As a preferred technical solution in one specific embodiment, the ZnSe shell has a bandgap greater than that of the inner core; the lattice constant of the material of the inner core differs from the lattice constant of the ZnSe shell by within +5%.

As a preferred technical solution in one specific embodiment, the distribution density of the branched-chain zinc carboxylate ligand on the surface of the shell is less than that of the long chain linear zinc carboxylate ligand, and the distribution density of the branched-chain zinc carboxylate ligand on the surface of the shell is less than that of the short chain linear zinc carboxylate ligand.

According to the present disclosure, the distribution density of the branched-chain zinc carboxylate ligand is less than that of the long chain linear zinc carboxylate ligand, and is also less than that of the short chain linear zinc carboxylate ligand, which is more conducive to increasing the coverage density of the short chain linear zinc carboxylate. Overall, the surface is fully coordinated. Additionally, the binding effect of the branched-chain zinc carboxylate ligand and the short chain linear zinc carboxylate on the surface is weaker than that of a conventional long chain linear zinc carboxylate, thus resulting in higher surface activity, and promoting the growth rates of the various facets to approximate each other, which is favorable for the formation of spherical morphology and achieving better size monodispersity. Additionally, the tensile strain of the inner core borne by different facets is evenly alleviated, ensuring that the tensile strain borne by the ZnSe shell is significantly released on the premise of maintaining high crystallinity.

As a preferred technical solution in one specific embodiment, a ZnS shell is further provided on the surface of the ZnSe shell. The ZnS shell may have a thickness of 4 monolayers (MLs) or 3 MLs or less.

According to the present disclosure, the surface of the ZnSe shell is coated with the ZnS shell, and the PLQY efficiency is significantly improved although the FWHM is widened.

Specifically, the ZnS shell includes 1-3 ZnS ML structures, e.g., 1, 1.5, 2, 2.5, or 3 ZnS ML structures, preferably 1.5-2.5 ZnS ML structures.

More specifically, the quantum dot includes the inner core and the ZnSe shell located on the surface of the inner core, the quantum dot has an FWHM of 6-23 nm, e.g., 6-10 nm, or 10-15 nm, or 15-20 nm, 20 nm, 21 nm, 22 nm, or 23 nm.

In a case that the quantum dot further includes the ZnS shell, the quantum dot has an FWHM of 6-29 nm, e.g., 6-10 nm, or 10-15 nm, or 15-20 nm, or 20-25 nm, or 25 nm, 26 nm, 27 nm, 28 nm, or 29 nm.

As a preferred technical solution in one specific embodiment, a linear, long chain of the long chain linear zinc carboxylate has 16-28 C atoms, e.g., 16, 17, 18, 19, 20, 21, 22, 23, 24, 25, 26, 27, or 28.

Specifically, the long chain linear zinc carboxylate ligand in the present disclosure includes, but is not limited to, zinc palmitate, zinc stearate, zinc oleate, zinc erucate, zinc docosanecarboxylate, or zinc octacosanecarboxylate, etc.

A short chain of the short chain linear zinc carboxylate has 6 C atoms or less, e.g., 2, 3, 4, 5, or 6, preferably 2-3; specifically, the first short chain linear zinc carboxylate includes zinc acetate and/or zinc propionate.

The branched-chain zinc carboxylate has a structure represented by formula (I):

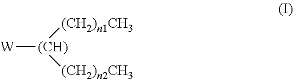

wherein in formula (I), n1 is 5-6, and n2 is 7-8; w is a carboxyl group.

In another specific embodiment, the present disclosure provides a preparation method for a quantum dot, including the following steps:
performing a first mixing of an inner core of a quantum dot, a first Se source, a long chain linear zinc carboxylate, a first short chain linear zinc carboxylate, and a first non-coordinating reaction medium to obtain a first reaction system, and carrying out a first heat treatment to obtain a core-shell quantum dot with a first shell thickness;
performing a second mixing of the core-shell quantum dot with the first shell thickness, a second Se source, a branched-chain zinc carboxylate, a second short chain linear zinc carboxylate, and a second non-coordinating reaction medium to obtain a second reaction system, and carrying out a second heat treatment to obtain the quantum dot,
wherein the quantum dot includes an inner core and a ZnSe shell located on a surface of the inner core; the ZnSe shell includes at least 4 ZnSe monolayers, and the quantum dot is a spherical quantum dot.

The long chain linear zinc carboxylate in the present disclosure can be formed by the reaction of zinc acetate and a long-chain carboxylic acid, and then used as a zinc ligand and a zinc source for preparing the quantum dot; similarly, the branched-chain zinc carboxylate is obtained by first mixing and reacting zinc acetate and a branched-chain carboxylic acid, and then used as a zinc ligand for preparing the quantum dot.

According to the preparation method provided by the present disclosure, the ZnSe shell coating the inner core is obtained through a two-step preparation process. In the first step, the long chain linear zinc carboxylate and the first short chain linear zinc carboxylate are used as ligands (also used as zinc sources) to give a first shell with a relatively thin thickness. Then, in the second step, the branched-chain zinc carboxylate and a second short chain linear zinc carboxylate are used as ligands (also being zinc sources), where the obtained ZnSe shell is further epitaxially grown, such that the tensile strain of the ZnSe shell due to lattice mismatch is significantly alleviated, while a weaker hydrodynamic force and a compression strain are generated on the inner core quantum dot (QD). The photoluminescence (PL) of the QD can be significantly improved through the interaction of the strains described above, resulting in a PL quantum yield of close to 100% between the core and shell, mono-exponential PL decay dynamics, and improved photophysical and photochemical stability of the quantum dot.

In the preparation process of the present disclosure, the preparation sequence and the selection of ligand types are indispensable. In the first step, the combination of the long chain linear zinc carboxylate and the first short chain linear zinc carboxylate is used for growing a thin ZnSe layer, allowing the crystal structure to maintain a virtually defect-free zinc-blende structure. Subsequently, the combination of the branched-chain zinc carboxylate and the second short chain linear zinc carboxylate is employed in the second step. The strong steric hindrance of the branched-chain zinc carboxylate results in only a small portion being coordinated to the surface (but it is sufficient to maintain the stability of the nanocrystalline colloid). Then, the remaining surface is adequately coordinated by the second short chain linear zinc carboxylate. Because the combination of the branched-chain zinc carboxylate and the second short chain linear zinc carboxylate causes higher activity of the whole surface (the binding effect is not as strong as that of the long chain linear zinc carboxylate), and anions and cations are introduced in a dropwise manner in the reaction, the growth process tends to be mainly driven by a thermodynamic force, and the surface atoms undergo reorganization towards a spherical shape. Ultimately, the obtained quantum dot is uniform in size, exhibits excellent dispersibility, has spherical morphology, and possesses an almost defect-free zinc-blende structure. If the preparation sequence is reversed, during the early stage of the ZnSe shell growth, the branched-chain zinc carboxylate and the short chain linear zinc carboxylate ligands result in excessively high surface activity of the inner core, leading to poor crystallinity of the ZnSe shell. This affects the further homogeneous growth of the thicker ZnSe shell and also impacts the photoluminescence efficiency of the quantum dot. However, lacking of any ligand structure during the preparation process will lead to the rapid accumulation of strain energy in the ZnSe shell due to lattice mismatch. Ultimately, to release this strain, partial island-like particles will come up, thereby affecting the further homogeneous growth of the ZnSe shell.

As a preferred technical solution in another specific embodiment, the ratio of the molar amount of the first short chain linear zinc carboxylate to the molar amount of the long chain linear zinc carboxylate is 0-0.25 excluding 0, e.g., 0.001, 0.01, 0.1, 0.15, 0.2, or 0.25.

In the present disclosure, if the ratio of the molar amount of the first short chain linear zinc carboxylate to the molar amount of the long chain linear zinc carboxylate is too high, meaning that an excessive amount of the first short chain linear zinc carboxylate is added, it would result in too many short chain linear zinc carboxylate coordination sites on the surface of the ultimate quantum dot, thereby destroying the colloidal stability of the quantum dot.

The ratio of the molar amount of Se in the first Se source to the sum of the molar amount of the long chain linear zinc carboxylate and the first short chain linear zinc carboxylate is 0-0.2 excluding 0, e.g., 0.01, 0.05, 0.1, 0.15, or 0.2.

As a preferred technical solution in another specific embodiment, a linear, long chain of the long chain linear zinc carboxylate has 16-28 C atoms, e.g., 16, 17, 18, 19, 20, 21, 22, 23, 24, 25, 26, 27, or 28.

Specifically, the long chain linear zinc carboxylate in the present disclosure includes, but is not limited to, zinc palmitate, zinc stearate, zinc oleate, zinc erucate, zinc docosanecarboxylate, or zinc octacosanecarboxylate, etc.

As a preferred technical solution in another specific embodiment, a short chain of the first short chain linear zinc carboxylate has 6 C atoms or less, e.g., 2, 3, 4, 5, or 6, preferably 2-3; specifically, the first short chain linear zinc carboxylate includes zinc acetate and/or zinc propionate.

As a preferred technical solution in another specific embodiment, the first non-coordinating reaction medium includes Vaseline and/or octadecene, preferably Vaseline and octadecene.

In the present disclosure, Vaseline is added to the first non-coordinating reaction medium. Vaseline can significantly expand the range of candidate precursors for cations and anions. Vaseline is a paste (mixture) of long-chain saturated hydrocarbons (with a boiling point above 300° C.), which can form a semi-fluid gel (i.e., Gel) when mixed with a certain amount of ODE. If an inorganic (or organic) compound can be ground into a fine powder (about 100 meshes) or co-dissolved with a gel at 100° C., the compound can be stably dispersed in a semi-fluid gel as a gel precursor (or ligand). In the present technical solution, the Se monomer and the short chain linear zinc carboxylate used are typically insoluble in a non-coordinating organic solvent. Therefore, Vaseline can be used to disperse these precursors into a homogeneous medium. Through equipment like an automatic sampler, the precursors can be continuously, uniformly, and automatically introduced into the reaction precursor, ensuring the homogeneous growth of the ZnSe shell under thermodynamic control.

As a preferred technical solution in another specific embodiment, the first mixing includes:
firstly, mixing the inner core of the quantum dot, the long chain linear zinc carboxylate, and the first non-coordinating reaction medium, and then adding the first Se source and the first short chain linear zinc carboxylate.

As a preferred technical solution in another specific embodiment, the first heat treatment is performed at 280-300° C., e.g., 280° C., 290° C., or 300° C.

As a preferred technical solution in another specific embodiment, the core-shell quantum dot with the first shell thickness has a shell thickness less than or equal to 2 nm, e.g., 0.5 nm, 1 nm, 1.5 nm, or 2 nm.

In the present disclosure, if the thickness of the shell with the first shell thickness is too great, it will lead to an increased strain for the binding of the straight-chain zinc carboxylate ligand to the surface of the quantum dot, such that stacking faults grow, and the subsequent homogeneous growth of ZnSe of the second shell is affected.

As a preferred technical solution in another specific embodiment, the ratio of the molar amount of the second short chain linear zinc carboxylate to the molar amount of the branched-chain zinc carboxylate is 0-0.5 excluding 0, e.g., 0.001, 0.1, 0.2, 0.3, 0.4, or 0.5.

In the present disclosure, if the ratio of the molar amount of the second short chain linear zinc carboxylate to the molar amount of the branched-chain zinc carboxylate is too high, meaning that an excessive amount of the second short chain linear zinc carboxylate is added, the surface of the quantum dot may be covered with too many short chain linear zinc carboxylate ligands, thereby destroying the colloidal stability of the quantum dot.

The ratio of the molar amount of Se in the second Se source to the sum of the molar amount of the branched-chain zinc carboxylate and the second short chain linear zinc carboxylate is 0-0.33 excluding 0, e.g., 0.01, 0.05, 0.1, 0.15, 0.2, 0.25, 0.3, or 0.33.

As a preferred technical solution in another specific embodiment, the branched-chain zinc carboxylate has a structure represented by formula (I):

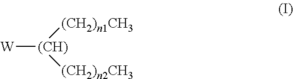

wherein in formula (I), n1 is 5-6, and n2 is 7-8; w is a carboxyl group.

As a preferred technical solution in another specific embodiment, a short chain of the second short chain linear zinc carboxylate has 6 C atoms or less, e.g., 2, 3, 4, 5, or 6, preferably 2-3; specifically, the second short chain linear zinc carboxylate includes zinc acetate and/or zinc propionate.

As a preferred technical solution in another specific embodiment, the second non-coordinating reaction medium includes Vaseline and/or octadecene, preferably Vaseline and octadecene.

In the present disclosure, Vaseline is added to the second non-coordinating reaction medium. Vaseline can significantly expand the range of candidate precursors for cations and anions. Vaseline is a paste (mixture) of long-chain saturated hydrocarbons (with a boiling point above 300° C.), which can form a semi-fluid gel when mixed with a certain amount of ODE. If an inorganic (or organic) compound can be ground into a fine powder (about 100 meshes) or co-dissolved with a gel at 100° C., the compound can be stably dispersed in a semi-fluid gel as a gel precursor (or ligand). In the present technical solution, the Se monomer and the short chain linear zinc carboxylate used are typically insoluble in a non-coordinating organic solvent. Therefore, Vaseline can be used to disperse these precursors into a homogeneous medium. Through equipment like an automatic sampler, the precursors can be continuously, uniformly, and automatically introduced into the reaction precursor, ensuring the homogeneous growth of the ZnSe shell under thermodynamic control.

As a preferred technical solution in another specific embodiment, the second mixing includes:
mixing the core-shell quantum dot with the first shell thickness, the branched-chain zinc carboxylate, and the second non-coordinating reaction medium, and then adding the second Se source and the second short chain linear zinc carboxylate.

As a preferred technical solution in another specific embodiment, the second heat treatment is performed at 280-300° C., e.g., 280° C., 290° C., or 300° C.

As a preferred technical solution in another specific embodiment, a solution after the second heat treatment is subjected to a purification treatment, and a product after the purification treatment is subjected to a ZnS coating treatment.

The purification treatment in the present disclosure is a conventional technical means, and any achievable technical means known to those skilled in the art are applicable to the present disclosure.

Specifically, the ZnS coating treatment includes mixing a sulfur source, a third short chain linear zinc carboxylate, a medium chain linear carboxylic acid, a long straight-chain carboxylic acid, and a third non-coordinating reaction medium, and performing a third heat treatment to obtain a quantum dot coated with ZnS.

According to the present disclosure, the ZnS coating treatment is performed by means of synergistic cooperation of three ligands, namely, the third short chain linear zinc carboxylate, the medium chain linear carboxylic acid, and the long straight-chain carboxylic acid. On one hand, the combination of straight-chain zinc carboxylates with different chain lengths forms an entropic ligand combination capable of significantly enhancing intramolecular vibration and rotational freedom. For large-sized quantum dots, the solubility of the colloidal quantum dots can be significantly enhanced. On the other hand, the medium and short-chain carboxylic acids, among the ligands with different chain lengths, can fully passivate the surface by virtue of their small steric hindrance, which is conducive to improving photoluminescence efficiency.

More specifically, a saturated short chain of the third short chain linear zinc carboxylate has 6 C atoms or less, e.g., 2, 3, 4, 5, or 6, preferably 2.

The third short chain linear zinc carboxylate may include zinc acetate and/or zinc propionate.

A linear, medium chain of the medium chain linear carboxylic acid has 8-14 C atoms, e.g., 8, 9, 10, 11, 12, 13, or 14, and the long straight-chain carboxylic acid includes oleic acid.

The third non-coordinating reaction medium includes Vaseline and/or octadecene.

The third heat treatment is performed at 300-310° C., e.g., 300° C., 305° C., or 310° C.

The third heat treatment is performed for 15-40 min, e.g., 15 min, 20 min, 25 min, 30 min, 35 min, or 40 min.

The quantum dot prepared by any one of the preparation methods described above has excellent optical properties. More specifically, in a case that the quantum dot includes the inner core and the ZnSe shell located on the surface of the inner core, the quantum dot has an FWHM of 6-23 nm, e.g., 6-10 nm, and/or 10-15 nm, and/or 15-20 nm, and/or 20-23 nm, 20 nm, 21 nm, 22 nm, or 23 nm.

In a case that the quantum dot further includes the ZnS shell, the quantum dot has an FWHM of 6-29 nm, e.g., 6-10 nm, or 10-15 nm, or 15-20 nm, or 20-25 nm, or 25 nm, 26 nm, 27 nm, 28 nm, or 29 nm.

The quantum dot prepared by any one of the preparation methods described above exhibits a zinc-blende structure; the tensile strain borne by the ZnSe shell is 0-3%; the compression strain borne by the inner core is 1-3%. The quantum dot has an average roundness greater than or equal to 0.8, more preferably greater than or equal to 0.9; the quantum dot has an average solidity greater than or equal to 0.8. In some embodiments, the quantum dot has a particle size of 4-12 nm.

In some embodiments, the ZnSe shell of the quantum dot includes 4-16 ZnSe monolayers.

Further, the preparation method for a quantum dot according to another specific embodiment of the present disclosure can be used for preparing the quantum dot described in the above specific embodiments.

In one application embodiment, the present disclosure provides a composition including the quantum dot described in one specific embodiment or the quantum dot prepared by the preparation method described in another specific embodiment.

In one application embodiment, the present disclosure provides an optoelectronic device including the quantum dot described in one specific embodiment or the quantum dot prepared by the preparation method described in another specific embodiment. The optoelectronic device may be various displays, light sources, lighting, personal computers (e.g., mobile personal computers), cellular phones, digital cameras, electronic notepads, electronic dictionaries, electronic game consoles, medical devices (e.g., electronic thermometers, sphygmomanometers, blood glucose meters, pulse measurement devices, pulse wave measurement devices, electrocardiogram display devices, ultrasonic diagnostic devices, endoscope display devices), fish finders, various measurement devices, measurement instruments (e.g., instruments for vehicles, airplanes, ships), projectors, and the like.

### Example 1

The example provides a quantum dot including the quantum dot provided in one specific example described above.

The quantum dot includes a CdSe inner core and a ZnSe shell located on the surface of the CdSe inner core; the ZnSe shell includes 7 ZnSe monolayers.

The surface ligands of the quantum dot include zinc stearate ligands, zinc 2-hexyl decanoate ligands (abbreviated as Zn(2hDe)₂), and zinc acetate ligands, and the quantum dot is a spherical quantum dot.

The ZnSe shell has a bandgap greater than that of the inner core; the lattice constant of the material of the inner core differs from the lattice constant of the ZnSe shell by within +5%.

The distribution density of the zinc 2-hexyl decanoate ligands on the surface of the shell is less than that of the zinc stearate ligands, and the distribution density of the zinc 2-hexyl decanoate ligands on the surface of the shell is less than that of the zinc acetate ligands.

The example further provides a preparation method for the quantum dot described above and the method is based on the preparation method provided in another specific example.

### (1) Preparation of Corresponding Preparation Raw Materials:

Stearic acid (90+%), cadmium oxide (CdO, 99.998%), selenium powder (200 mesh, 99.999%), 1-octadecene (ODE, 90%), zinc acetate (Zn(Ac)₂, >99.99%), and Vaseline were purchased from Sigma-Aldrich. Stearic acid (98+%) and 2-hexyl decanoic acid (98%+) were purchased from Tokyo Chemical Industry. Trioctylphosphine (TOP) was purchased from Alfa-Aesar. Other organic solvents were from Sinopharm Reagent.

### (2) Preparation of CdSe Inner Core:

Se powder (2 mmol) was dispersed in ODE (2 mL) by sonication for 5 min, into which melted Vaseline (3 mL) was added. A Se-Gel precursor (0.4 mol/L) was prepared. CdO (0.8 mmol) and stearic acid (3.2 mmol) were loaded into a 50 mL three-neck flask with 24 mL of ODE. After being stirred and argon bubbled for 10 min, the mixture was heated to 280° C. to obtain a colorless solution. After the mixture was allowed to cool down to 250° C. in air, 1 mL of Se-Gel was injected quickly into the flask. After growing for 8 min, one dose of Se-Gel was loaded into a syringe and dropwise added to the reaction flask at 1.0 mL/h by an automated syringe pump until the CdSe inner core with a targeted size was obtained.

### (3) Preparation of ZnSe Shell by Two Steps:

\textcircled{1}: Zn(Ac)₂ (0.2 mmol) and stearic acid (0.6 mmol) were heated to 150° C. in a 25 mL three-neck flask and retained at this temperature for 20 min to remove acetic acid under Ar flow. Into the solution after removing acetic acid, 8 mL of ODE was added and the mixture was heated to 290° C. Then, the ODE solution (0.2 mL) containing 68 nmol of the purified CdSe inner core was rapidly injected into the flask. Immediately, 4 mL of Zn(Ac)₂-Gel and 4 mL of Se-Gel (Se-Gel (0.05 mol/L) was obtained by dispersing Se powder (0.2 mmol) in ODE (2 mL) and Vaseline (2 mL) by sonication for 5 min) were separately loaded in two syringes and dropwise added to the reaction flask at 3 mL/h through automated syringe pumps. About 20 min later, the reaction was stopped by allowing the reaction mixture to cool down to room temperature, yielding thin-shell CdSe/ZnSe core/shell quantum dots (core-shell quantum dots with the first shell thickness); and

\textcircled{2}: Zn(Ac)₂ (0.2 mmol) and 2-hexyl decanoic acid (0.44 mmol) were heated to 150° C. in a 25 mL three-neck flask and retained at this temperature for 20 min to remove acetic acid under Ar flow. Into the solution after removing acetic acid, 8 mL of ODE was added and the mixture was heated to 290° C. Then, the ODE solution (0.2 mL) containing 68 nmol of the purified thin-shell CdSe/ZnSe core/shell quantum dots was rapidly injected into the flask. Immediately, 4 mL of Zn(Ac)₂-Gel and 4 mL of Se-Gel (Se-Gel (0.05 mol/L) was obtained by dispersing Se powder (0.2 mmol) in ODE (2 mL) and Vaseline (2 mL) by sonication for 5 min) were separately loaded in two syringes and dropwise added to the reaction flask at 3 mL/h through automated syringe pumps. About 40 min later, the reaction was stopped by allowing the reaction mixture to cool down to room temperature to obtain the quantum dot.

### Example 2

The example differs from Example 1 in that the ZnSe shell in the example includes 2 ZnSe monolayers (CdSe/2ZnSe).

The preparation method differs from that of Example 1 in that ZnSe was prepared with only the first step of the reaction, i.e., the reaction with Zn(Ac)₂ (0.2 mmol) and stearic acid (0.6 mmol) as the main zinc source.

The rest of the preparation method and parameters remain the same as in Example 1.

### Example 3

The example differs from Example 1 in that the ZnSe shell in the example includes 4 ZnSe monolayers (CdSe/4ZnSe).

The preparation method differs from that of Example 1 in that the reaction time for the second step of ZnSe shell growth was 20 min.

The rest of the preparation method and parameters remain the same as in Example 1.

### Example 4

The example differs from Example 1 in that the ZnSe shell in the example includes 12 ZnSe monolayers (CdSe/12ZnSe).

The preparation method differs from that of Example 1 in that the reaction time for the second step of ZnSe shell growth was 120 min.

The rest of the preparation method and parameters remain the same as in Example 1.

### Example 5

The example differs from Example 1 in that the ZnSe shell in the example includes 16 ZnSe monolayers (CdSe/16ZnSe).

The preparation method differs from that of Example 1 in that the reaction time for the second step of ZnSe shell growth was 180 min.

The rest of the preparation method and parameters remain the same as in Example 1.

### Example 6

The example differs from Example 1 in that in the example the surface of the ZnSe shell is further coated with a ZnS shell, the ZnS shell includes 1.9 ZnS monolayers (CdSe/7ZnSe+1.9ZnS), and the average size of the CdSe inner core is 2.7 nm.

Specifically, the ligands on the surface of the ZnS shell are zinc acetate, zinc 2-hexyl decanoate, and zinc oleate.

The example further provides a preparation method for the quantum dot described above, and the preparation method differs from Example 1 in that:

Step (4) was performed after Step (3) of Example 1.

### (4) Preparation of ZnS Shell:

Firstly, isolation and purification of CdSe/ZnSe core/shell quantum dots were performed. The crude reaction solution from Step (2) was mixed with 200 μL of acetic acid in a vial and kept at 100° C. for 3 min. The mixed solution was centrifuged at 4000 rpm for about 2 min. The supernatant was removed quickly, and the precipitate was mixed with 2 mL of toluene and kept at 100° C. for 2 min to dissolve Vaseline. The supernatant was then removed quickly, and the precipitate was mixed with 100 μL of acetic acid and 5 mL of methanol. After the mixture was kept at 80° C. for 4 min, the vial was centrifuged at 4000 rpm for about 20 s. The supernatant was removed, and 100 μL of oleic acid and 2 mL of toluene were mixed with the precipitate to obtain a clear solution of the quantum dots (QDs). 5 mL of ethanol was added to the QD solution to precipitate the oleate-coordinated CdSe/ZnSe core/shell QDs. After centrifugation and decantation, the purified CdSe/ZnSe core/shell QD precipitate was obtained.

### Preparation of ZnS Shell:

Zn(Ac)₂ (0.5 mmol), capric acid (0.4 mmol), oleic acid (0.8 mmol), and ODE (4 mL) were loaded in a 50 mL three-neck flask. The mixture was heated to 310° C. and then the ODE solution (0.5 mL) containing 34 nmol of the purified CdSe/ZnSe core/shell QDs prepared above was rapidly injected into the reaction mixture in the flask. Simultaneously, 3.5 mL of S precursor solution (obtained by dispersing S powder (0.5 mmol) in TOP (1 mL) and ODE (4 mL) by sonication for 5 min) was injected quickly into the flask. After 20 minutes of epitaxial growth, the reaction was stopped by cooling down the mixture to room temperature. CdSe/CdS/ZnS QDs were then precipitated once using ethanol and redispersed in toluene to obtain the quantum dot (with a CdSe/CdS/ZnS core/shell/shell structure).

The rest of the preparation method and parameters remain the same as in Example 1.

### Example 7

The example differs from Example 6 in that the ZnS shell in the example includes 0.4 ZnS monolayer (CdSe/7ZnSe+0.4ZnS).

The preparation method differs from that of Example 6 in that the reaction time for the second step of ZnS shell growth was 5 min.

The rest of the preparation method and parameters remain the same as in Example 6.

### Example 8

The example differs from Example 6 in that the ZnS shell in the example includes 1.3 ZnS monolayers (CdSe/7ZnSe+1.3ZnS).

The preparation method differs from that of Example 6 in that the reaction time for the second step of ZnS shell growth was 10 min.

The rest of the preparation method and parameters remain the same as in Example 6.

### Example 9

The example differs from Example 6 in that the ZnS shell in the example includes 2.4 ZnS monolayers (CdSe/7ZnSe+2.4ZnS).

The preparation method differs from that of Example 6 in that the reaction time for the second step of ZnS shell growth was 30 min.

The rest of the preparation method and parameters remain the same as in Example 6.

### Example 10

The example differs from Example 6 in that the ZnS shell in the example includes 2.7 ZnS monolayers (CdSe/7ZnSe+2.7ZnS).

The preparation method differs from that of Example 6 in that the reaction time for the second step of ZnS shell growth was 40 min.

The rest of the preparation method and parameters remain the same as in Example 6.

### Example 11

The example differs from Example 6 in that the ZnS shell in the example includes 3 ZnS monolayers (CdSe/7ZnSe+3ZnS).

The preparation method differs from that of Example 6 in that the reaction time for the second step of ZnS shell growth was 45 min.

The rest of the preparation method and parameters remain the same as in Example 6.

### Example 12

The example differs from Example 6 in that the ZnS shell in the example includes 3.5 ZnS monolayers (CdSe/7ZnSe+3.5ZnS).

The preparation method differs from that of Example 6 in that the reaction time for the second step of ZnS shell growth was 55 min.

The rest of the preparation method and parameters remain the same as in Example 6.

### Comparative Example 1

The comparative example provides a quantum dot including a CdSe inner core and a ZnSe shell located on the surface of the CdSe inner core; the ZnSe shell includes 7 ZnSe monolayers.

The surface ligands of the quantum dot include zinc stearate.

The comparative example further provides a preparation method for the quantum dot, including the following steps:

### (1) Preparation of Corresponding Preparation Raw Materials:

Stearic acid (90+%), zinc chloride, cadmium oxide (CdO, 99.998%), selenium powder (200 mesh, 99.999%), 1-octadecene (ODE, 90%), zinc acetate (Zn(Ac)₂, >99.99%), and Vaseline were purchased from Sigma-Aldrich. Stearic acid (98+%) and palmitoyl chloride (97.0%) were purchased from Tokyo Chemical Industry. Trioctylphosphine (TOP) was purchased from Alfa-Aesar. Other organic solvents were from Sinopharm Reagent.

### (2) Preparation of CdSe Inner Core:

Se powder (2 mmol) was dispersed in ODE (2 mL) by sonication for 5 min, into which melted Vaseline (3 mL) was added. A Se-Gel precursor (0.4 mol/L) was prepared. CdO (0.8 mmol) and stearic acid (3.2 mmol) were loaded into a 50 mL three-neck flask with 24 mL of ODE. After being stirred and argon bubbled for 10 min, the mixture was heated to 280° C. to obtain a colorless solution. After the mixture was allowed to cool down to 250° C. in air, 1 mL of Se-Gel was injected quickly into the flask. After growing for 8 min, one dose of Se-Gel was loaded into a syringe and dropwise added to the reaction flask at 1.0 mL/h by an automated syringe pump until the CdSe inner core with a targeted size was obtained.

### (2) Preparation of ZnSe Inner Core:

Zn(Ac)₂ (0.2 mmol) and stearic acid (0.6 mmol) were heated to 150° C. in a 25 mL three-neck flask and retained at this temperature for 20 min to remove acetic acid under Ar flow. Into the solution after removing acetic acid, 8 mL of ODE was added and the mixture was heated to 290° C. Then, the ODE solution (0.2 mL) containing 68 nmol of the purified CdSe inner core was rapidly injected into the flask. Immediately, 4 mL of Se-Gel (with 0.05 mol/L of Se) (obtained by dispersing Se powder (0.2 mmol) in ODE (2 mL) and Vaseline (2 mL) by sonication for 5 min) was separately loaded in two syringes and dropwise added to the reaction flask at 3 mL/h through automated syringe pumps. About 60 min later, the reaction was stopped by allowing the reaction mixture to cool down to room temperature, yielding CdSe/ZnSe core/shell quantum dots.

### Comparative Example 2

The comparative example provides a quantum dot including a CdSe inner core and a ZnSe shell located on the surface of the CdSe inner core; the ZnSe shell includes 7 ZnSe monolayers.

The surface ligands of the quantum dot include zinc stearate and chloride ions.

The comparative example further provides a preparation method for the quantum dot, including the following steps:

### (1) Preparation of Corresponding Preparation Raw Materials:

Stearic acid (90+%), zinc chloride, cadmium oxide (CdO, 99.998%), selenium powder (200 mesh, 99.999%), 1-octadecene (ODE, 90%), zinc acetate (Zn(Ac)₂, >99.99%), and Vaseline were purchased from Sigma-Aldrich. Stearic acid (98+%) and palmitoyl chloride (97.0%) were purchased from Tokyo Chemical Industry. Trioctylphosphine (TOP) was purchased from Alfa-Aesar. Other organic solvents were from Sinopharm Reagent.

### (2) Preparation of CdSe Inner Core:

Se powder (2 mmol) was dispersed in ODE (2 mL) by sonication for 5 min, into which melted Vaseline (3 mL) was added. A Se-Gel precursor (0.4 mol/L) was prepared. CdO (0.8 mmol) and stearic acid (3.2 mmol) were loaded into a 50 mL three-neck flask with 24 mL of ODE. After being stirred and argon bubbled for 10 min, the mixture was heated to 280° C. to obtain a colorless solution. After the mixture was allowed to cool down to 250° C. in air, 1 mL of Se-Gel was injected quickly into the flask. After growing for 8 min, one dose of Se-Gel was loaded into a syringe and dropwise added to the reaction flask at 1.0 mL/h by an automated syringe pump until the CdSe inner core with a targeted size was obtained.

### (2) Preparation of ZnSe Inner Core:

Zn(Ac)₂ (0.2 mmol) and stearic acid (0.6 mmol) were heated to 150° C. in a 25 mL three-neck flask and retained at this temperature for 20 min to remove acetic acid under Ar flow. Into the solution after removing acetic acid, 8 mL of ODE was added and the mixture was heated to 290° C. Then, the ODE solution (0.2 mL) containing 68 nmol of the purified CdSe inner core was rapidly injected into the flask. Immediately, 4 mL of Se—Cl-Gel (with 0.05 mol/L of Se and 0.005 mol/L of Cl) (obtained by dispersing Se powder (0.2 mmol) and palmitoyl chloride (0.02 mmol) in ODE (2 mL) and Vaseline (2 mL) by sonication for 5 min) was separately loaded in two syringes and dropwise added to the reaction flask at 3 mL/h through automated syringe pumps. About 20 min later, the reaction was stopped by allowing the reaction mixture to cool down to room temperature, yielding CdSe/ZnSe core/shell quantum dots (core-shell quantum dots with the first shell thickness).

### Comparative Example 3

The comparative example provides a quantum dot including a CdSe inner core and a ZnSe shell located on the surface of the CdSe inner core; the ZnSe shell includes 7 ZnSe monolayer s.

The surface ligands of the quantum dot include zinc stearate and zinc acetate.

The comparative example further provides a preparation method for the quantum dot, and the preparation method differs from Comparative Example 1 in that 4 mL of Zn(Ac)₂-Gel was dropwise added to the reaction flask at 3 mL/h through an automatic syringe pump along with the ZnSe shell growth.

The rest of the preparation method and parameters remain the same as in Example 1.

### Comparative Example 4

The comparative example provides a quantum dot including a CdSe inner core and a ZnSe shell located on the surface of the CdSe inner core; the ZnSe shell includes 7 ZnSe monolayers.

The surface ligands of the quantum dot include zinc 2-hexyl decanoate and zinc acetate.

The comparative example further provides a preparation method for the quantum dot, and the preparation method differs from Comparative Example 3 in that 0.6 mmol of 2-hexyldecanoic acid was loaded into the reaction flask rather than stearic acid.

The rest of the preparation method and parameters remain the same as in Example 3.

### 1. Optical Measurements.

(1) UV-vis spectra were taken on an Agilent Cary 4000 UV-vis spectrophotometer.
(2) PL spectra were recorded using an Agilent Cary Eclipse photoluminescence spectrophotometer.
(3) PL decay dynamics were measured on a time-correlated single-photon counting (TCSPC) spectrofluorometer (FLS920, Edinburgh Instruments, UK), and the nanocrystals were excited by a 405 nm picosecond laser diode with a 2 MHz repetition rate.
(4) The absolute PL QY was measured using a calibrated Ocean Optics FOIS-1 integrating sphere coupled with a QE65000 spectrometer.
(5) Single nanocrystal optical measurements: The purified QDs were dispersed into a toluene solution containing 3 wt % PMMA, followed by spin-coating onto a clean quartz cover glass. The final density of the nanocrystals on the cover glass was 0.1-0.01/μm². Optical properties were tested on an epi-photoluminescence inverted microscopy system (Olympus IX 83) incorporated with a spectrometer (Andor 193i, equipped with 300 L/mm grating and iXon Ultra 897 EMCCD). An excitation beam from 395 nm picosecond laser (PiLas-PiL037X, with a repetition rate of 1 MHz) was focused onto the object plane with an objective lens (oil-immersed, 60×), and emission from the QDs was collected with the same objective lens. Laser signal was blocked by a long pass filter with a cutoff wavelength of 400 nm and then projected onto the entrance slit of the spectrometer. Spectral signal was acquired using the “kinetic mode” of EMCCD with 1 s exposure per frame, adopting average results from 20 frames.

### 2. Structure Measurements:

(1) TEM measurements. The QDs were deposited onto a copper grid with an ultrathin carbon film before images were acquired on a Hitachi 7700 transmission electron microscope at 100 kV.
(2) XRD measurements were obtained on a Rigaku Ultimate-IV X-ray diffractometer at 40 KV/40Ma with Cu Kα line (λ=1.5418 Å). Powder samples of the purified nanocrystals were placed onto glass substrates.
(3) Raman measurements were performed using a home-made Raman system in confocal geometry, and all samples were prepared by dissolving the purified nanocrystals in cyclohexane in a quartz cuvette. The excitation source was a diode-pumped solid-state laser (Cobalt, 04-01-473) at 473 nm. The Raman scattering light was collected using a Princeton Instrument SP2750 monochromator with a Pylon 400BRX CCD camera.

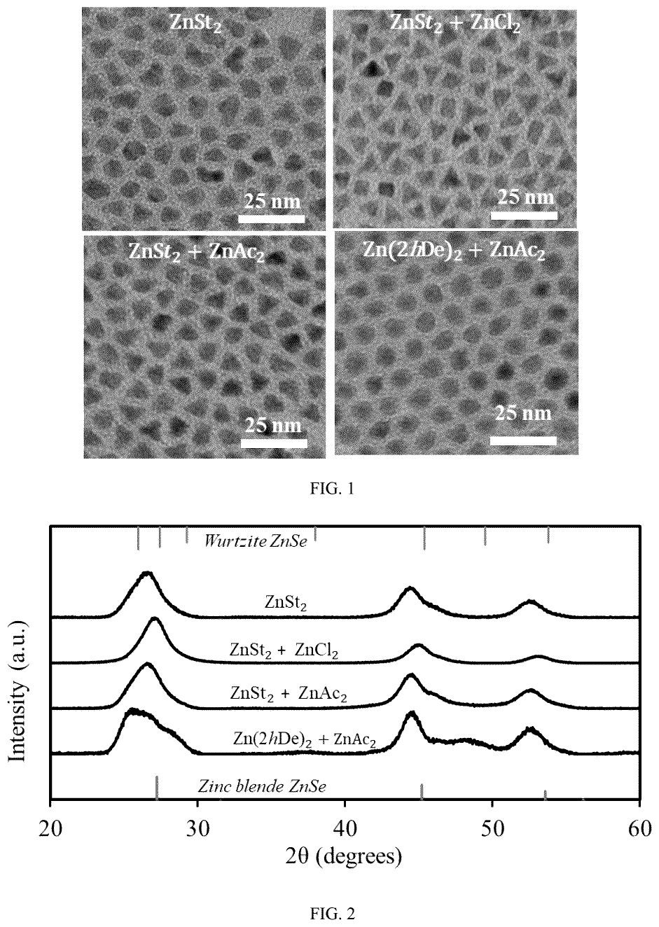

FIG. 1 shows TEM images of quantum dots according to Comparative Examples 1-4.

FIG. 2 is an XRD graph of the quantum dots according to Comparative Examples 1-4.

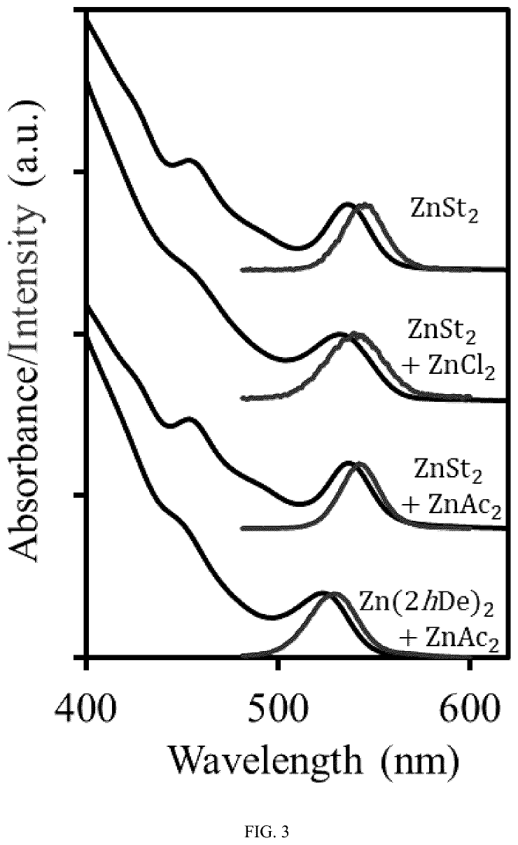

FIG. 3 is a graph of UV-Vis spectra and PL spectra of the quantum dots according to Comparative Examples 1-4.

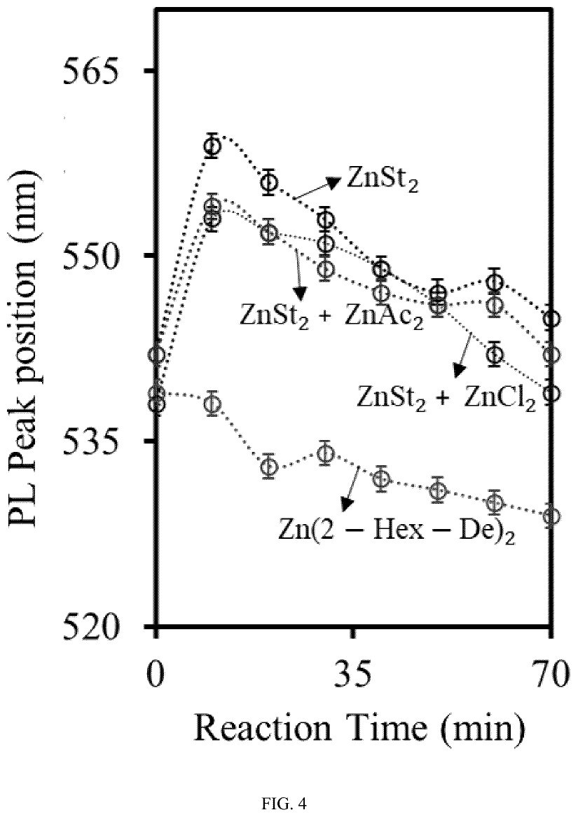

FIG. 4 shows a comparison of PL peak positions of the quantum dots according to Comparative Examples 1-4.

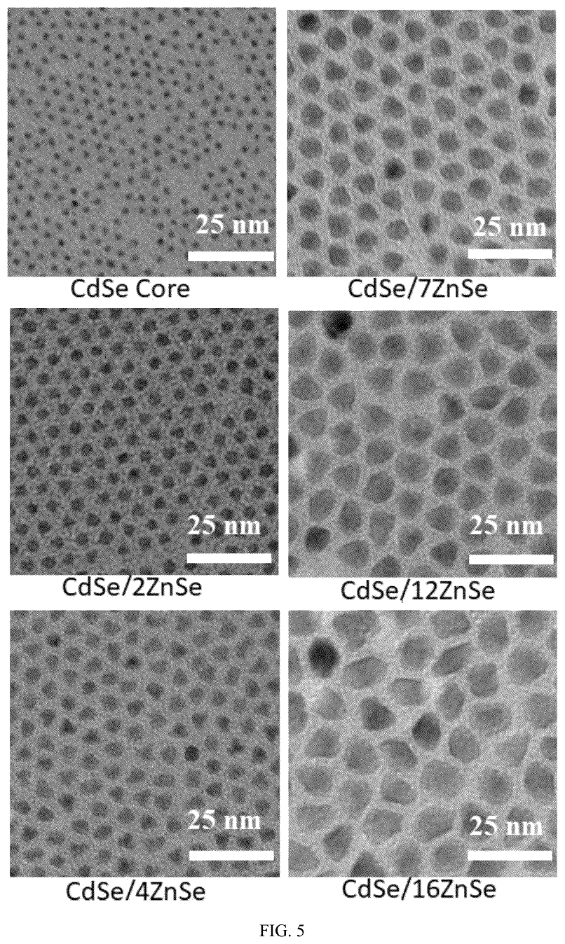

FIG. 5 shows TEM images of quantum dots according to Examples 1-5 and a TEM image of the same CdSe inner core in Examples 1-6.

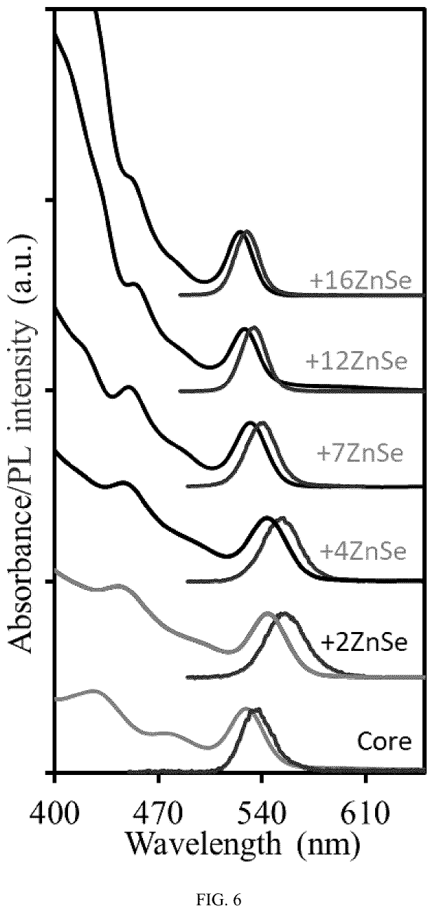

FIG. 6 is a graph of UV-Vis spectra and PL spectra of the quantum dots according to Examples 1-5.

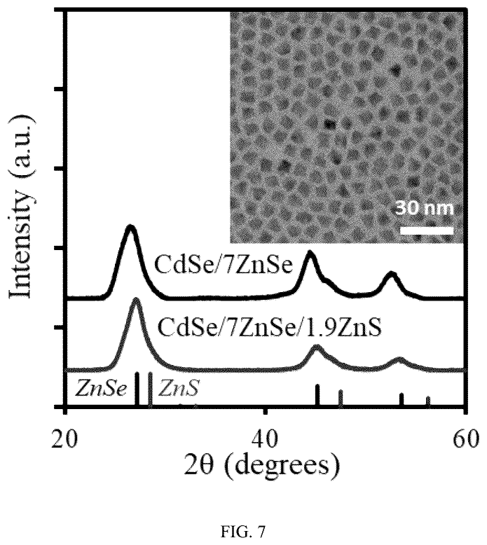

FIG. 7 shows an XRD graph of quantum dots according to Examples 1 and 6 and a TEM image of the quantum dots according to Example 6.

As can be seen from FIGS. 1-4, in the process of growing the ZnSe shell, different zinc carboxylate ligands have significantly different effects on the morphology, size, and photoluminescent properties of the quantum dot. With zinc stearate (ZnSt₂) as the zinc precursor and the sole source of surface ligands, the resulting CdSe/ZnSe core/shell quantum dots are irregular in shape (with surface concavities and sharp corners). Chloride ions in the form of ZnCl₂ mixed with ZnSt₂ (ZnSt₂+ZnCl₂) indeed result in the formation of CdSe/ZnSe core/shell quantum dots with better-controlled facets, but the shape of the product remains irregular. PL and UV-Vis peaks of the final product are noticeably broader compared to the reaction where zinc stearate is used as the sole zinc precursor. Instead of inorganic chloride ions, acetate ions were applied as small ligands to release the surface-ligands strain, such that the final product reduces shape irregularity mostly by eliminating sharp corners. The (Zn(2hDe)₂+ZnAc₂) reaction forms spherical quantum dots, indicating fully releasing the surface-ligands strain and no facet-selective growth. Compared to the zinc-blende phase structure of the first three, the product from the reaction exhibits a mixed structure of zinc-blende and wurtzite phases.

As can be seen from FIGS. 5 and 6, combining the advantages of two different zinc carboxylates, Step 1 makes use of the (ZnSt₂+ZnAc₂) reaction to epitaxially grow two monolayers of non-alloy ZnSe shell onto the CdSe core quantum dots. The (Zn(2hDe)₂+ZnAc₂) ligand system in Step 2 allows epitaxial growth of the thick ZnSe shell by further releasing the ligand-induced strain. XRD testing confirms that the lattice constant of CdSe/2ZnSe quantum dots is close to that of pure CdSe, indicating relatively small surface-ligands strain in a ligand system with moderate surface-ligands strain yet good control of crystal structure. The strong surface-ligands strain of the thick-shell quantum dots in Step 2 can be readily released by the (Zn(2hDe)₂+ZnAc₂) ligand system, and the alloying problem and formation of mixed crystal structures of this ligand system can be avoided by the thin-ZnSe shell epitaxially grown in Step 1.

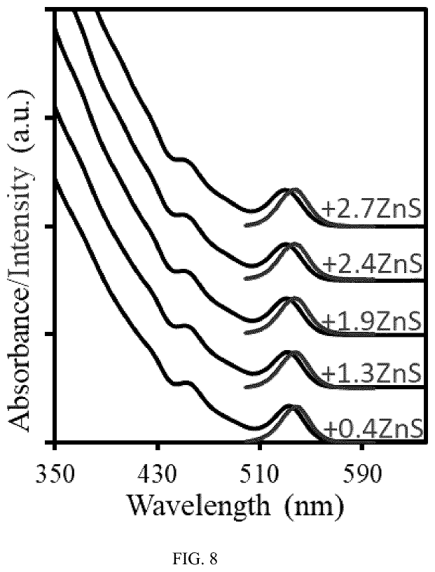

FIG. 8 is a graph of UV-Vis spectra and PL spectra of the quantum dots according to Examples 6-10.

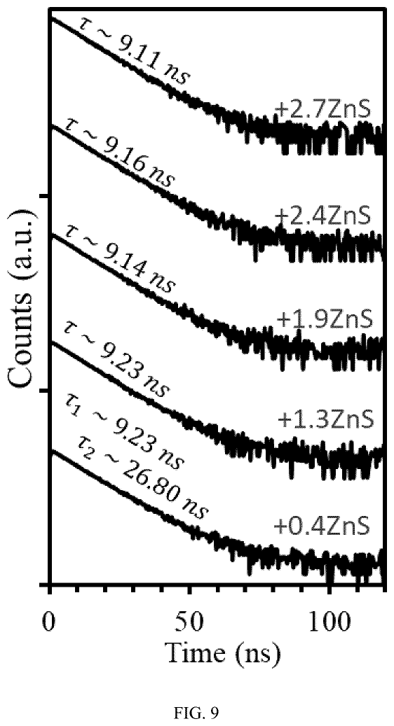

FIG. 9 is a PL decay dynamics curve graph of quantum dots according to Examples 6-10.

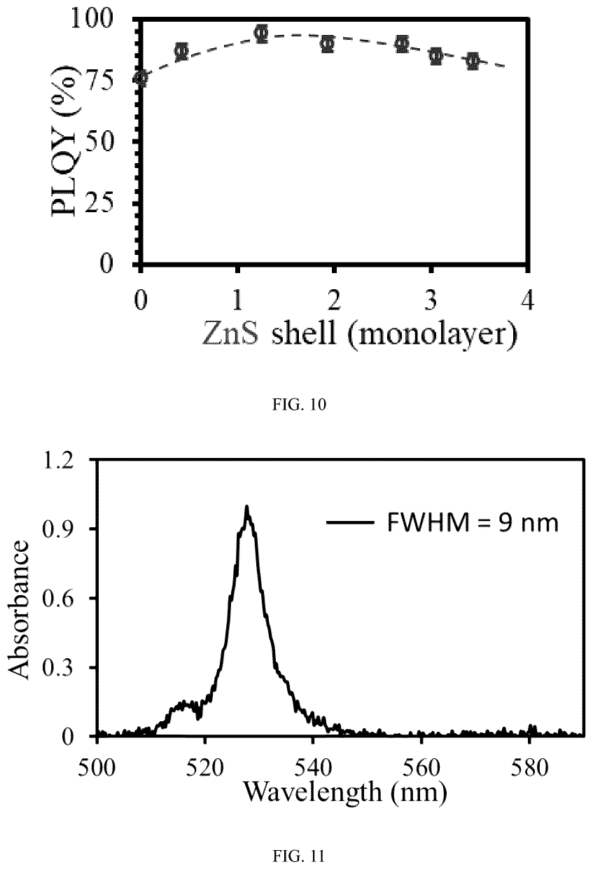

FIG. 10 shows the relationship between the ZnS shell thickness and PLQY of quantum dots according to Examples 6-12.

As can be seen from FIGS. 6-10, upon the epitaxy of additional ZnS shell onto CdSe/7ZnSe quantum dots, PL and UV-Vis spectral characteristics remain essentially unaltered. This confirms that, with the successful epitaxy of the ZnSe shell, the emission color of high-quality CdSe/ZnSe/ZnS core/shell/shell quantum dots can be well-controlled and close to that of the CdSe core quantum dots. Beyond 3 monolayers of the outer ZnS shell, the spectra become significantly broadened. Epitaxial growth of 1-3 monolayers of the ZnS shell can reproducibly yield CdSe/7ZnSe/ZnS core/shell/shell quantum dots with mono-exponential PL decay dynamics, indicating uniform and controlled epitaxy of the ZnS shell. For quantum dots with 0 to 1 monolayer of outer ZnS shell, there is a minor long-lifetime component. For quantum dots with more than 3 monolayers of outer ZnS shell, an additional short-lifetime component is observed (data not shown). With more than 1 monolayer of the ZnS shell, the PLQY of the quantum dots can maintain more than 90%.

FIG. 11 is a graph of the PL spectrum of a single quantum dot in Examples 6-10.

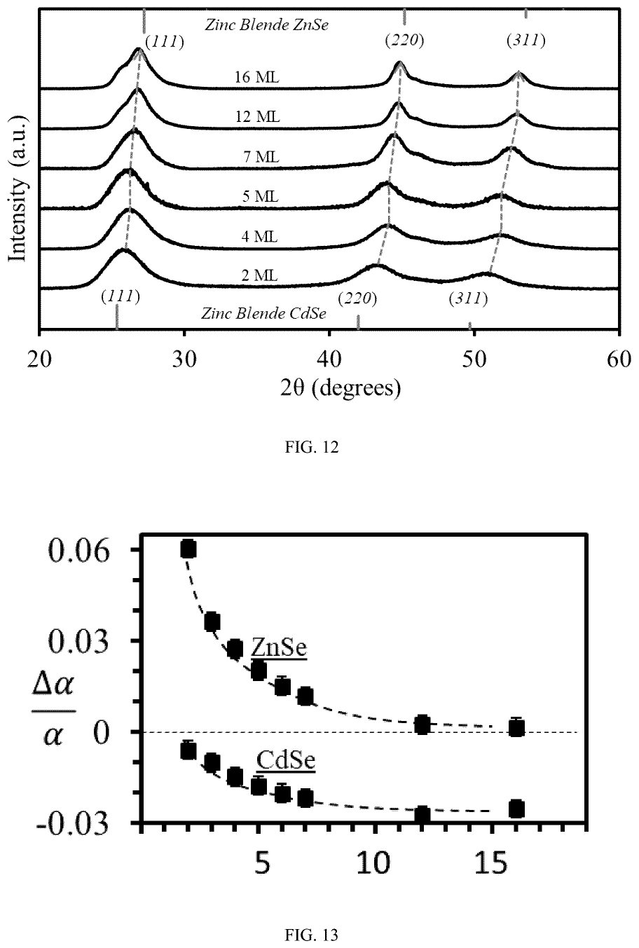

FIG. 12 is an XRD graph of CdSe/ZnSe quantum dots (the preparation method of which is omitted with reference to Examples 1-5) with different shell thicknesses according to Examples 1-5 and other Examples of the present disclosure.

FIG. 13 shows the change rate of the relative lattice constants of the core and the shell of CdSe/ZnSe quantum dots (the preparation method of which is omitted with reference to Examples 1-5) with different shell thicknesses (the abscissa represents the number of ZnSe monolayers) according to Examples 1-5 and other Examples of the present disclosure.

As can be seen from FIG. 11, the FWHM of the CdSe/ZnSe/ZnS quantum dots of Examples 6-10 can reach an extremely narrow width of around 9 nm at a single particle level at room temperature.

As can be seen from FIG. 12, the lattice constant of the CdSe/2ZnSe quantum dots in Step 1 is close to that of pure CdSe quantum dots, indicating relatively small surface-ligands strain in a ligand system with moderate surface-ligands strain and controlled crystal structure. In Step 2, the (Zn(2hDe)₂+ZnAc₂) ligand system quantum dots exhibit a zinc-blende structure, indicating that the ZnSe shell in the second step achieved controlled epitaxy.

As can be seen from FIG. 13, albeit with a very small volume fraction, the compression strain on the CdSe core lattice is always small and with a limited lattice variation. Presumably, the compression strain to the CdSe core quantum dots is hydrodynamic and radially symmetric, leading to small effects on the CdSe cores. Conversely, the tensile strain on the ZnSe shell is asymmetric and may be released at the inorganic ligand interface. Though the ZnSe shell bears most part of the CdSe—ZnSe lattice strain, the strain is limited to the ZnSe shell next to the CdSe—ZnSe interface, about 7 ZnSe monolayers, and is released to the outer part of the ZnSe shell.

The structural characteristics of the quantum dots provided in Examples 1-12 and Comparative Examples 1˜4 are shown in Table 1:

TABLE 1

| | | Tensile | Compression | Particle | | | |
|---|---|---|---|---|---|---|---|
| | Presence | strain borne | strain borne | size of | | | |
| | of ZnS | by ZnSe | by inner core | quantum | Average | Average | FWHM |
| | shell | shell (%) | (%) | dot (nm) | roundness | solidity | (nm) |
| Example 1 | No | 1 | 2 | 7 | 0.92 | 0.85 | 23 |
| Example 2 | No | 3 | 1 | 4 | 0.9 | 0.83 | 29 |
| Example 3 | No | 1.5 | 1.7 | 5 | 0.86 | 0.8 | 26 |
| Example 4 | No | 0.2 | 3 | 9 | 0.83 | 0.8 | 22 |
| Example 5 | No | 0.1 | 3 | 12 | 0.83 | 0.8 | 21 |
| Example 6 | Yes | 1 | 2 | 8 | 0.8 | 0.8 | 27 |
| Example 7 | Yes | 1 | 2 | 7.2 | 0.88 | 0.83 | 24 |
| Example 8 | Yes | 1 | 2 | 7.7 | 0.85 | 0.8 | 26 |
| Example 9 | Yes | 1 | 2 | 8.3 | 0.8 | 0.77 | 28 |
| Example 10 | Yes | 1 | 2 | 8.5 | 0.75 | 0.7 | 29 |
| Example 11 | Yes | 1 | 2 | 8.6 | 0.73 | 0.7 | 30 |
| Example 12 | Yes | 1 | 2 | 8.9 | 0.7 | 0.6 | 31 |
| Comparative | No | 3 | 4 | 7 | 0.6 | 0.5 | 26 |
| Example 1 | | | | | | | |
| Comparative | No | 1 | 3 | 7 | 0.8 | 0.8 | 29 |
| Example 2 | | | | | | | |
| Comparative | No | 1.5 | 3 | 7 | 0.8 | 0.8 | 26 |
| Example 3 | | | | | | | |
| Comparative | No | 1 | 3 | 7 | 0.9 | 0.85 | 30 |
| Example 4 | | | | | | | |

Table 2 shows the optical properties provided by Examples 1-12 and Comparative Examples 1-4.

TABLE 2

| | Fluorescence lifetime of PL | |
|---|---|---|
| | decay dynamics curve | PLQY |
| Example 1 | 12 ns | >85% |
| Example 2 | 13 ns | 65% |
| Example 3 | 12 ns | 70% |
| Example 4 | 11 ns | 70% |
| Example 5 | 10 ns | 65% |
| Example 6 | 9 ns | 87% |
| Example 7 | 9 ns | >90% |
| Example 8 | 9 ns | >90% |
| Example 9 | 9 ns | >90% |
| Example 10 | 9 ns | 90% |
| Example 11 | 9 ns | 85% |
| Example 12 | 9 ns | 82% |
| Comparative Example 1 | 12 ns | 55% |
| Comparative Example 2 | 12 ns | <30% |
| Comparative Example 3 | 12 ns | 60% |
| Comparative Example 4 | 12 ns | <3% |

As can be seen from Tables 1 and 2:

During the growth of ZnSe with different thicknesses, the strains borne by the inner core and the ZnSe shell change continuously, leading to variations in the size distribution and the morphology of the quantum dots in the growth process. Results from Table 1 regarding roundness and solidity indicate that the optimal size monodispersity and uniform morphology are achieved when the ZnSe shell includes about 4-9 layers (Example 1). FIG. 2 demonstrates that under these conditions, the luminescent properties are optimal, with photoluminescence efficiency reaching around 85% without ZnS shell protection. After the growth of about 2 layers of ZnS, the photoluminescence efficiency can exceed 90% (Example 6). In cases where the number of ZnSe layers is either too many or too few (Examples 2-5), the morphology and the luminescent properties of the quantum dots are both reduced (compared to Example 1). Compared to the comparative examples, the crystal structure properties and the luminescent properties of the quantum dots in Examples 2-5 exhibit superior characteristics. This is attributed to the two-step growth solution of ZnSe, where straight-chain zinc carboxylate and branched-chain zinc carboxylate were used successively accompanied by the introduction of short chain linear zinc carboxylate with small volume steric hindrance throughout the reaction process. The method effectively alleviates the lattice strain between the core and the shell, as well as the surface strain between the ligands and the surface, allowing for thorough surface passivation. Therefore, both the crystal structure and luminescent properties reach an excellent level. Significantly, the ligands in the comparative examples have their own problems when used alone. For example, in Comparative Example 3, the morphology is not uniform and the photoluminescence efficiency does not reach an excellent level. In Comparative Example 3, the photoluminescence efficiency is extremely low and the FWHM is large, mainly due to defects caused by the poor crystallinity of the quantum dots and stacking faults arising therefrom.

Examples 6-12 involve the epitaxial growth of the ZnS shell on the CdSe/7ZnSe from Example 1. Example 6 shows that when less than 1 layer of ZnS is grown, PLQY has increased significantly to around 87%, and the photoluminescence spectrum is broadened, but the overall morphology is substantially uniform and the size monodispersity is good. With the increase of the ZnS shell, i.e., in Examples 6-10, when the ZnS shell includes 1-2.7 layers, the PLQY can reach more than 90%, and the emission color of the high-quality CdSe/ZnSe/ZnS core/shell/shell quantum dots can be well controlled. The transient photoluminescence shows a mono-exponential decay, and the monodispersity of the overall nanocrystal is good, with uniform morphology maintained. When the ZnS shell includes more than 3 layers (Examples 11 and 12), the photoluminescence efficiency begins to decrease. In general, a different entropic ligand system was employed for the epitaxial growth of ZnS in the form of a common zinc precursor, i.e., a mixture of zinc ((Ac)₂), zinc oleate (Zn(Ol)₂), and zinc undecanoate (Zn(De)₂). The system can release ligand-induced strain and maintain high colloidal stability. The FWHM of a single-particle photoluminescence spectrum of the high-quality CdSe/ZnSe/ZnS core/shell/shell quantum dots can reach about 9 nm at room temperature.

### Examples 13-16

Example 13 differs from Example 6 in that the CdSe inner core has an average size of 2.6 nm.

Example 14 differs from Example 6 in that the CdSe inner core has an average size of 3 nm.

Example 15 differs from Example 6 in that the CdSe inner core has an average size of 4 nm.

Example 16 differs from Example 6 in that the CdSe inner core has an average size of 5 nm.

Except for the differences described above, the preparation methods and parameters in Examples 13-16 remain the same as in Example 6.

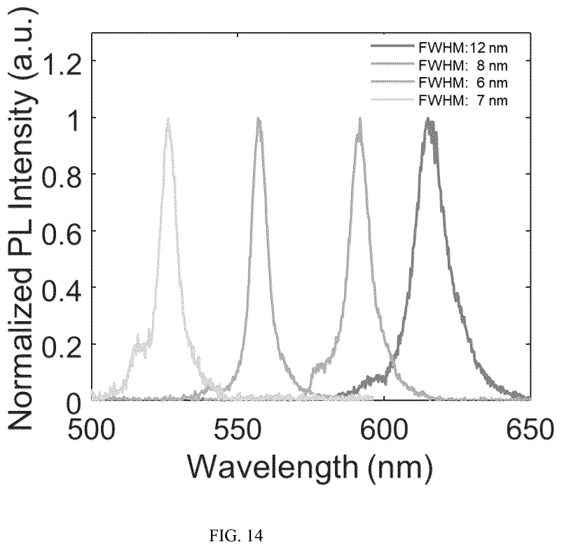

The products of Examples 13-16 have an average size in the range of 8-9.5 nm with different PL peak positions, and the single quantum dot PL spectra of Examples 13-16 are shown in FIG. 14, demonstrating the narrowest photoluminescence FWHM reported so far to the knowledge of the inventor. The ultra-narrow photoluminescence FWHM is very beneficial for quantum dots in display applications. The photoluminescent property of a single quantum dot is already excellent. Further improvements, such as increasing the proportion of high-quality quantum dots, e.g., enhancing the uniformity of quantum dot distribution, can further improve the photoluminescent (FWHM) property of an ensemble of quantum dots.

In conclusion, according to the present disclosure, the ZnSe shell coating the inner core is obtained through a two-step preparation process. In the first step, the long chain linear zinc carboxylate and the first short chain linear zinc carboxylate are used as ligands (also used as zinc sources) to give a first shell with a relatively thin thickness. Then, in the second step, the branched-chain zinc carboxylate and a second short chain linear zinc carboxylate are used as ligands (also being zinc sources), where the obtained ZnSe shell is further epitaxially grown, such that a strong asymmetric tensile strain of the ZnSe shell is generated, while a weaker hydrodynamic force and a compression strain are generated on the inner core QD. The photoluminescence (PL) of the QD can be significantly improved through the interaction of the strains described above, resulting in a PL quantum yield of close to 100% between the core and shell, mono-exponential PL decay dynamics, and improved photophysical and photochemical stability of the quantum dot.

The above describes in detail the preferred embodiment of the present disclosure, however, the present disclosure is not limited to the specific details in the above embodiment, and within the scope of the technical conception of the present disclosure, a variety of simple variations of the technical solution of the present disclosure can be carried out, and all of these simple variations belong to the scope of protection of the present disclosure.

It is also to be noted that the various specific technical features described in the above specific embodiments may be combined in any suitable manner without contradiction, and in order to avoid unnecessary repetition, the present disclosure does not separately describe the various possible combinations.

In addition, the various different embodiments of the present disclosure can also be combined in any way, and as long as they do not contradict the idea of the present disclosure, they should likewise be regarded as the contents disclosed in the present disclosure.

1. A quantum dot, comprising an inner core and a ZnSe shell located on a surface of the inner core, wherein the ZnSe shell comprises at least 4 ZnSe monolayers, surface ligands of the quantum dot comprise long chain linear zinc carboxylate ligands, branched-chain zinc carboxylate ligands, and short chain linear zinc carboxylate ligands, and the quantum dot is a spherical quantum dot.

2. The quantum dot according to claim 1, wherein the quantum dot exhibits a zinc-blende structure; a tensile strain borne by the ZnSe shell is 0-3%; a compression strain borne by the inner core is 1-3%.

3. The quantum dot according to claim 1, wherein the quantum dot has an average roundness greater than or equal to 0.8, more preferably greater than or equal to 0.9; the quantum dot has an average solidity greater than or equal to 0.8.

4. The quantum dot according to claim 1, wherein a distribution density of the branched-chain zinc carboxylate ligand on the surface of the shell is less than that of the long chain linear zinc carboxylate ligand, and the distribution density of the branched-chain zinc carboxylate ligand on the surface of the shell is less than that of the short chain linear zinc carboxylate ligand.

5. The quantum dot according to claim 4, wherein the quantum dot comprises the inner core and the ZnSe shell located on the surface of the inner core, the quantum dot has a full width at half maximum (FWHM) of 6-23 nm.

6. A preparation method for a quantum dot, wherein, comprising the following steps:
performing a first mixing of an inner core of a quantum dot, a first Se source, a long chain linear zinc carboxylate, a first short chain linear zinc carboxylate, and a first non-coordinating reaction medium to obtain a first reaction system, and carrying out a first heat treatment to obtain a core-shell quantum dot with a first shell thickness;
performing a second mixing of the core-shell quantum dot with the first shell thickness, a second Se source, a branched-chain zinc carboxylate, a second short chain linear zinc carboxylate, and a second non-coordinating reaction medium to obtain a second reaction system, and carrying out a second heat treatment to obtain the quantum dot,
wherein the quantum dot comprises an inner core and a ZnSe shell located on a surface of the inner core; the ZnSe shell comprises at least 4 ZnSe monolayers, and the quantum dot is a spherical quantum dot.

7. The preparation method for a quantum dot according to claim 6, wherein a ratio of a molar amount of the first short chain linear zinc carboxylate to a molar amount of the long chain linear zinc carboxylate is 0-0.25 excluding 0;
preferably, a ratio of a molar amount of Se in the first Se source to a sum of the molar amount of the long chain linear zinc carboxylate and the first short chain linear zinc carboxylate is 0-0.2 excluding 0;
preferably, a long chain linear of the long chain linear zinc carboxylate has 16-28 C atoms.

8. The preparation method for a quantum dot according to claim 6, wherein a short chain of the first short chain linear zinc carboxylate has 6 C atoms or less;
preferably, the first non-coordinating reaction medium comprises Vaseline and/or octadecene.

9. The preparation method for a quantum dot according to claim 6, wherein the first mixing comprises:
firstly, mixing the inner core of the quantum dot, the long chain linear zinc carboxylate, and the first non-coordinating reaction medium, and then adding the first Se source and the first short chain linear zinc carboxylate;
preferably, the core-shell quantum dot with the first shell thickness has a shell thickness less than or equal to 2 nm.

10. The preparation method for a quantum dot according to claim 6, wherein a ratio of a molar amount of the second short chain linear zinc carboxylate to a molar amount of the branched-chain zinc carboxylate is 0-0.5 excluding 0;
preferably, a ratio of a molar amount of Se in the second Se source to a sum of the molar amount of the branched-chain zinc carboxylate and the second short chain linear zinc carboxylate is 0-0.33 excluding 0;
preferably, the branched-chain zinc carboxylate has a structure represented by formula (I): 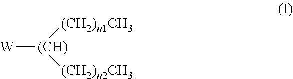
wherein in formula (I), n1 is 5-6, and n2 is 7-8; w is a carboxyl group.

11. The preparation method for a quantum dot according to claim 6, wherein a short chain of the second short chain linear zinc carboxylate has 6 C atoms or less,
preferably, the second non-coordinating reaction medium comprises Vaseline and/or octadecene.

12. The preparation method for a quantum dot according to claim 6, wherein the second mixing comprises:
mixing the core-shell quantum dot with the first shell thickness, the branched-chain zinc carboxylate, and the second non-coordinating reaction medium, and then adding the second Se source and the second short chain linear zinc carboxylate.

13. The preparation method for a quantum dot according to claim 6, wherein a solution after the second heat treatment is subjected to a purification treatment, and a product after the purification treatment is subjected to a ZnS coating treatment;
the ZnS coating treatment comprises mixing a sulfur source, a third short chain linear zinc carboxylate, a medium chain linear carboxylic acid, a long straight-chain carboxylic acid, and a third non-coordinating reaction medium, and performing a third heat treatment to obtain a quantum dot coated with ZnS;
preferably, a saturated short chain of the third short chain linear zinc carboxylate has 6 C atoms or less.

14. The preparation method for a quantum dot according to claim 13, wherein a linear, medium chain of the medium chain linear carboxylic acid has 8-14 C atoms, and the long straight-chain carboxylic acid comprises oleic acid;
preferably, the third non-coordinating reaction medium comprises Vaseline and/or octadecene.

15. A composition, comprising the quantum dot according to claim 1.

16. An optoelectronic device, comprising the quantum dot according to claim 1.

17. The quantum dot according to claim 1, wherein the ZnSe shell has a bandgap greater than that of the inner core, a lattice constant of a material of the inner core differs from a lattice constant of the ZnSe shell by within +5%.

18. The quantum dot according to claim 1, wherein a ZnS shell is further provided on the surface of the ZnSe shell, the ZnS shell comprises 1-3 ZnS monolayers, preferably 1.5-2.5 ZnS monolayers.

19. The quantum dot according to claim 1, wherein the ZnSe shell comprises 4-16 ZnSe monolayers.

20. The quantum dot according to claim 1, wherein the quantum dot further comprises the ZnS shell, the quantum dot has an FWHM of 6-29 nm.
